(19) United States
(12) Patent Application Publication
(10) Pub. No.: US 2026/0025929 A1
(43) Pub. Date: Jan. 22, 2026

(54) MANUFACTURING OF ELECTRIC CIRCUITS ON INSULATING COATINGS

(71) Applicants: OERLIKON METCO AG, WOHLEN, WOHLEN (CH); OERLIKON AM EUROPE GMBH, GARCHING (DE)

(72) Inventors: Jean-Charles GARMIER, VILLMERGEN (CH); Alexander Rudolf Gebhard BARTH, KONSTANZ (DE); Simon Vincent SANKARE, MÜNCHEN (DE)

(21) Appl. No.: 18/997,015

(22) PCT Filed: Jul. 12, 2023
(86) PCT No.: PCT/EP2023/000045

§ 371 Date: Jan. 18, 2025

Related U.S. Application Data
(60) Provisional application No. 63/392,241, filed on Jul. 26, 2022.

(51) Int. Cl. H05K 3/10; H05K 3/00; H05K 3/28

(52) U.S. Cl. CPC H05K 3/102; H05K 3/0029; H05K 3/103; H05K 3/28; H05K 2203/0528; H05K 2203/107; H05K 2203/128

(57) ABSTRACT

A process of forming an electric circuit on an insulating ceramic substrate or on an insulating ceramic layer of a substrate that includes depositing a conductive material over a surface of the ceramic substrate or layer; and directing a laser beam onto the conductive material over the ceramic substrate or layer and moving the laser beam relative to the ceramic substrate or layer along a predetermined pattern for the electric circuit, whereby the conductive material is melted over the ceramic substrate or layer to form a conductive track.

### BACKGROUND OF THE INVENTION

### 1. Field of the Invention

An electric circuit can be formed by applying an electrically conductive track pattern made from a metal alloy onto an electrically insulating surface.

### 2. Discussion of Background Information

Electric circuits, e.g., electric heaters for household goods or electric cars, are produced on insulating surfaces, e.g., aluminum oxide, using coating technologies such as thermal spray, plasma vapor deposition (PVD) or ink jet printing. The components are usually made from a metal base plate onto which either an insulating plate made from glass or ceramic is soldered on or an insulating ceramic coating is applied on. The most widely used method is the deposition of a ceramic coating based on aluminum oxide by thermal spray.

However, these methods, in addition to depositing an electrically conductive track onto the insulating surface, require additional processing steps, special toolings or maskings.

Thermal spray technology is widely used to form electrically conductive and structured layers. The main advantages of thermal spray technology are the high application rate, e.g., processing up to 150 g/min leading to process times of less than 5 minutes to cover 1 m² with 30 μm of a conductive material. In addition, the ability to deposit on three dimensional surfaces and the comparatively low material costs. However, at the same time, thermal spray coatings always require maskings to cover areas that must not be coated. Moreover, to produce a long meander-type conductive track via thermal spray technology requires either complex masking or post processing in which material is removed, e.g., by laser ablation. Both of these options generate costs in the range of the cost for the coating deposition. Special thermal spray technologies, such as the deposition processes of MESOSCRIBE of CVD Materials Corporation or ECOCOAT of ecoCOAT GmbH, Allershausen, Germany, require additional consumables and are orders of magnitude lower in processing speed in comparison to atmospheric plasma spray, electric arc wire spray and flame spray.

PVD produces thin film deposition with the advantage that floating masks, which can be easily applied and reused multiple times and/or refurbished multiple times, are sufficient. However, it has been found to be disadvantageous to use PVD in this type of application because PVD has a very low deposition rate, e.g., to deposit a sufficiently thick layer to form a heater would take minimum 10 hours per m² and therefore approximately 100 times longer than thermal spray, whereas a typical thickness for the deposited conductive track is in a range of 10-50 μm, and typically 15-30 μm. Thus, processing times for PVD can be in the range of about an hour for a single component. Moreover, as PVD requires vacuum conditions, this process disadvantageously prevents a continuous production setup.

Ink jet printing avoids the issue of masking or post-deposition structuring of thermal spray technology but is not without its disadvantages. In this regard, the printing material has to be made from a slurry which requires solvents and additives, the processing speed, e.g., 1-8 hours per m², is far lower compared to, e.g., thermal spray, and the printed material has to be post-treated in a drying and sintering step, which is time and energy consuming and is associated with the risk of crack formation or delamination due to the high thicknesses required.

### SUMMARY

Embodiments are directed to laser additive layer manufacturing (LALM) processes, such as, e.g., selective laser melting (SLM) technology, laser beam-powder bed fusion (LB-PBF) or laminated object manufacturing (LOM) machine processing, to deposit the electrically conductive track pattern onto an insulting surface. This technology combines the advantages of the above-mentioned technologies, such as high rate of production, high efficiency and reproducibility, and delivers a reliable, cost-effective product.

LALM processes significantly lower the material consumption, improve the efficiency of the production process and simplify the production process by not requiring maskings and/or post-processing. By way of non-limiting example, a conductive track, e.g., a Ni-, Fe- Cu- or Al-based alloy, can be deposited by a LALM process with a thickness of 10-50 μm at a processing rate comparable to, e.g., 1 to 2 times, the application rate for thermal spray technology onto a surface. Moreover, by way of non-limiting example, a meander-type electrical track can be applied via an LALM process on a 200 mm×200 mm plate made from, e.g., steel or aluminum alloy with an electrically insulated surface in a range of about a minute, which is orders of magnitude faster than both PVD and ink jet printing. However, unlike thermal spray technology, LALM processes do not require masking or a post processing steps, e.g., laser ablation, to form a meander type conductive pattern.

The LALM processes are far more efficient than the other known processes since there is no loss of material due to overspray. In this regard, powder material or foil supplied onto on the surface of the plate at a position that is not part of the conductive path being formed will not be treated by the laser and therefore not melted or changed in its morphology or composition. Moreover, this untreated material on the plate can be recaptured and reused. In addition to this higher efficiency with regard to the material consumption, LALM processes are also far lower in the consumption of electrical energy as compared to thermal spray technology, e.g., lowering the consumption of electricity to 10-20% compared to atmospheric plasma spraying and 50-70% compared to electric arc wire spraying.

The structure of an electrically conductive track produced by a LALM process will also be more homogenous compared to thermal spray or ink jet printing, so that the risk of hot spots formed from inconsistent electrical resistivity of the metal layer can be avoided. Further, the specific electrical resistivity of the electrically conductive track applied by an LALM process will be lower compared to thermal spray and ink jet printing due to a lower content of oxides forming in the deposition process and due to a lower porosity. In this way, the thickness of the electrically conductive track can be reduced as compared to the known art, which leads to lower amounts of material required to produce these electrically conductive tracks.

Also, unlike thermal spray technology and ink jet printing, LALM processes do not need post-processing to generate a pattern or to dry and sinter the material.

A LALM process, such as SLM, is like ink jet printing and PVD in that it is limited to forming the conductor on flat substrates, whereas thermal spray technology can be use on 3D surfaces. Due to the design of the electric circuit components for e.g. electric heaters applied to a flat surface, this the drawback is not a technical limitation.

Embodiments are directed to a process of forming an electric circuit on a substrate that includes depositing a conductive material on a ceramic surface on or of the substrate; and directing a laser beam onto the conductive material on the ceramic surface and moving the laser beam relative to the ceramic surface along a predetermined pattern for the electric circuit, whereby the conductive material is melted onto the ceramic surface to form a conductive track.

In embodiments, the process can be a laser additive layer manufacturing (LALM) process.

In other embodiments, the LALM may be a selective laser melting (SLM) process. The SLM process can be performed in a protective atmosphere, such as in a protective argon atmosphere, and the conductive material may include a conductive powder or a conductive foil.

According to other embodiments, the LALM may be a laser beam-powder bed fusion (LB-PBF) process. Further, the conductive material can include a conductive powder.

In accordance with still other embodiments, the LALM may be a laminated object manufacturing (LOM) machine. Further, the conductive material can include a conductive foil.

According to still other embodiments, the predetermined pattern for the electric circuit may be a meandering pattern.

In other embodiments, prior to depositing the conductive material, the process can further include at least one of: pre-patterning a surface to which the conductive track is to be adhered with the laser beam or applying a seed layer to which the conductive track is to be adhered.

In still other embodiments, to generate sufficient adhesion for the electrical heating track, the process may further include at least one of: reducing intensity of the laser beam, reducing pulse duration of the laser beam, or travel speed of a laser spot of the laser beam.

In accordance with still yet other embodiments, the conductive material may include a Ni-, Fe-, Al- or Cu-based alloy.

According to other embodiments, the substrate may be a metal or ceramic substrate.

In accordance with still yet other embodiments, the ceramic surface can be part of a ceramic layer formed over the substrate. The ceramic layer and the conductive track can be components of a coating system applied to the substrate. The process can further include applying an insulating layer over the conductive track; and forming conductive contacts over the insulating layer. The insulating layer and the conductive tracks may be components of the coating system. Moreover, before the ceramic layer is formed over the substrate, the process may further include applying a bond coat, as a component of the coating system, on the substrate. The ceramic layer can be formed on the bond coat.

Other exemplary embodiments and advantages of the present invention may be ascertained by reviewing the present disclosure and the accompanying drawing.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 shows an electric heating element formed from a coating system applied onto a substrate;

FIG. 2 shows an exemplary illustration of an LALM process forming a conductive track of a plate electric heater element on a ceramic substrate according to embodiments;

FIGS. 3A and 3B show exemplary illustrations of the construction of a plate electric heater element according to embodiments.

### DETAILED DESCRIPTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

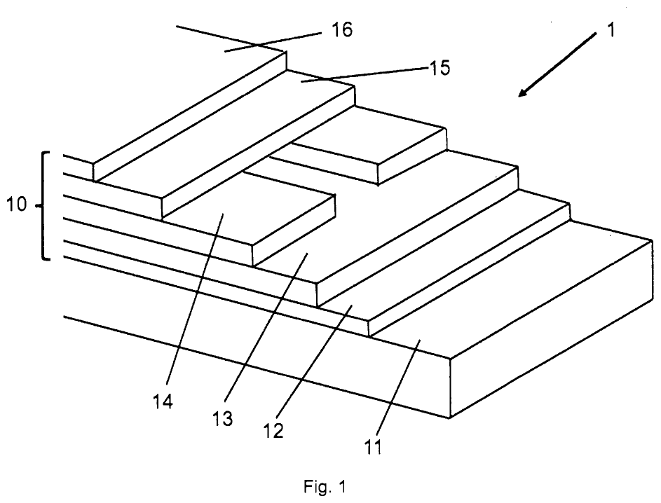

FIG. 1 illustrates an electric heating element (1), in which a coating system (10) is formed on a substrate (11). The coating system (10) is formed by an optional metallic bond coat (12), e.g., Ni-and Fe-based alloys, such as Ni 20Cr, Ni 5Al, AlSl 420, AlSl 316L, to improve adhesion of the heating component to a substrate (11) that is preferably made from, e.g., Al-alloys, mild steel, stainless steel. In other non-limiting embodiments, substrate (11) can be a ceramic substrate. A first insulating layer (13) comprised of an electrically insulating ceramic material, e.g., Al₂O₃ or other ceramic material or glass, is applied to electrically separate conductive heating tracks (14) from the substrate (11) or bond coat layer (12). The conductive heating track or tracks (14), which is or are formed via an additive layer manufacturing (LALM) process, comprised of an electrically conductive material, e.g., Ni 20Cr, NiCr, pure Ni, or Ni-, Fe-, Al- or Cu-based alloy. that is, in particular, a patterned electrically conductive layer that is applied, e.g., with a meandering pattern type layout.

A second insulating layer (15) comprised of an electrically insulating ceramic material, e.g., Al₂O₃ or other ceramic material or glass, is thermally sprayed onto and between conductive heating tracks (14), to electrically separate the conductive layer from the environment and to protect against accidental contact. Electrically conductive layer (16), e.g., copper or a copper-based alloy, is patterned at zones via mechanical masking during the thermal spray process to allow conductive heating tracks 14 to be connected to an external power source (not shown), e.g., by soldering.

The laser additive layer manufacturing (LALM) process according to embodiments can include a selective laser melting (SLM) process using powder or foil as a feeding material, a laser bed-powder bed fusion (LB-PBF) process using powder as a feeding material or a Laminated Object Manufacturing (LOM) machine process using, e.g., foil as a feeding material. SLM and LB-PBF are known processes intended to produce three dimensional structures, but not known in the art for applying coatings onto a substrate, as these processes can be technically limited to applications onto flat surfaces, limited to applying weldable alloys to metal surfaces and/or lacking productivity to build up coatings of several hundred micrometer in comparison to thermal spray. Similarly, LOM machine processes are known for producing three dimensional structures, but not for applying coatings onto a substrate. However, in seeking to address the deficiencies in the known art in the production of patterned electrically conductive tracks, the inventors found that LALM processes provide a unique set of properties leading to a one-step or additive process with higher efficiency and higher productivity than available in the known art.

The SLM process according to embodiments of the invention utilizes a deposition method that has been heretofore intended only for use on weldable and therefore metallic surfaces. In order to produce the electrically conductive heating tracks (14), e.g., a Ni-, Fe-, Al- or Cu-based alloy on a surface of insulating layer (13), e.g., aluminum oxide or other ceramic material or glass, special measures are taken, e.g., defining a set of processing parameters, preparing processing files of the tracks (14), spreading a thin layer of powder (i.e., 20 μm-120 μm) onto the insulating layer (13) and starting the laser melting processes. Depending on the physical properties of the deposited materials and insulating layer materials, the development of processing parameters is required.

Embodiments are directed to LALM processes to deposit the electrically conductive tracks pattern (14) onto a surface of insulating layer (13). This technology combines the advantages of the above-mentioned technologies, such as high productivity rate and reproducibility, and delivers a reliable, cost-effective product and at the same time reduces the number of processing steps.

Because LALM processes do not require masking or post-processing, such as laser ablation, forming the electrically conductive tracks pattern (14) on the insulating layer (13), these processes significantly lower the material consumption, improve the efficiency of the production process and simplify the production process. By way of non-limiting example, conductive tracks (14), e.g., a Ni-, Fe-, Al- or Cu-based alloy, can be deposited by LALM processes, e.g., SLM or LB-PBF using a conductive powder feeding materials or SLM or LOM machine processing using a conductive foil feeding material, with a thickness of 10-50 μm at a processing time comparable to the application rate for thermal spray technology. While the processing time for the material deposition is estimated to be at 50-200% in comparison with atmospheric plasma spray, these LALM processes do not require time consuming post-processing. By way of non-limiting example, a meandering pattern type electrical track can be applied via LALM processes on a 200 mm×200 mm plate made from, e.g., steel, aluminum or copper alloys in a range of about a minute, which is orders of magnitude faster than both PVD and ink jet printing. Moreover, unlike thermal spray technology, these LALM processes do not require time consuming pre-masking over the substrate or time-consuming post-processing, e.g., laser ablation, to form the meandering conductive pattern.

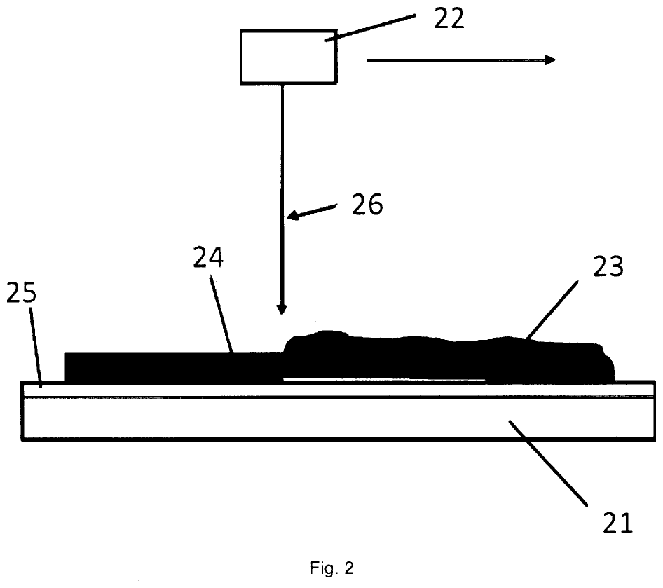

By way of non-limiting example, FIG. 2 shows an exemplary illustration of an SLM or LB-PBF process forming a conductive track (24) on an insulating layer (25) over a substrate (21). In this non-limiting exemplary embodiment, the substrate (21) can be, e.g., a ceramic substrate, but other substrate materials, including metal substrates, can be used without departing from the invention as disclosed. However, it is noted that a bond coat (not shown) can be optionally applied between substrate (21) and insulation (25). In this illustrated exemplary embodiment, a conductive track (24) is formed from, e.g., a Ni-, Fe-, Al- or Cu-based alloy powder (23) deposited onto the insulating layer (25). While FIG. 2 is a side view, it is understood that the conductive track can be formed in a meandering pattern. A laser (22) moving relative to substrate (21) can be moved over a predetermined conductive track pattern and emit a beam onto the alloy powder (23) to melt alloy powder (23) to form conductive track (24).

In embodiments, the SLM or LB-PBF processes can be performed by dispensing alloy powder (23) along the predetermined conductive track pattern followed by laser treatment/melting of alloy powder (23) into conductive track (24). Alternatively, alloy powder (23) can be deposited over the surface of the substrate (21) in the SLM or LB-PBF processes and conductive track (24) can be formed as the laser beam (26) melts the alloy powder (23) as the laser (22) moves relative to substrate (21) along a predetermined conductive track pattern. In either event, it is readily apparent that there is no loss of material due to overspray with these LALM processes. Further, as any alloy powder (23) that is not treated with the laser beam (26) in the LALM processes remains untreated/unmelted in its morphology or composition, after formation of the conductive track (24) is complete, untreated/unmelted alloy powder (23) and can be recaptured and reused.

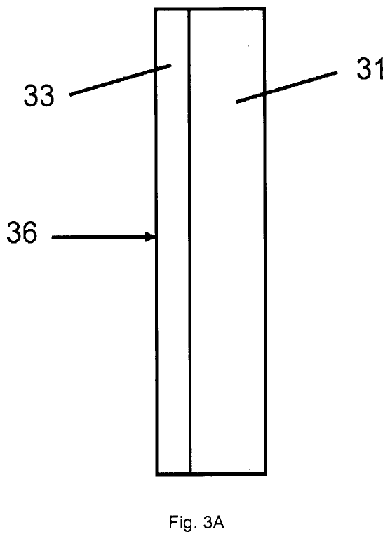

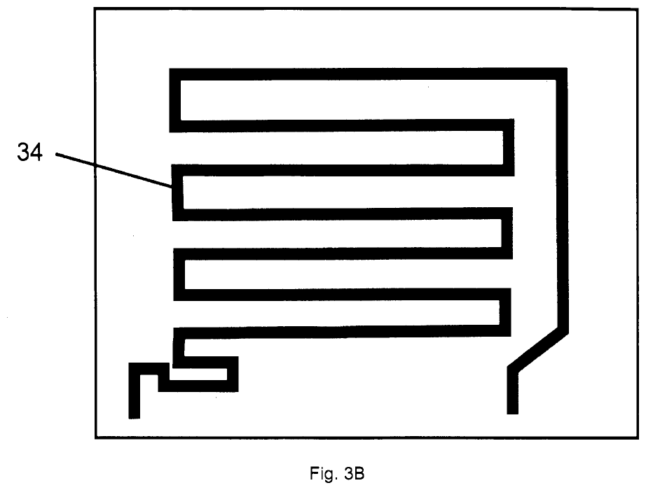

In other embodiments, in which, e.g., only a single thin layer is required to be deposited for the electric track, in lieu of a powder based LALM processes, a thin foil of metal can be used to produce the electrically conductive track via SLM. Alternatively, it may be advantageous to deposit the single thin layer electric track via LOM machine processing. In a non-limiting exemplary embodiment, FIGS. 3A shows a side view and 3B shows a top view of the conductive plate heating element formed from a conductive foil, e.g., a Ni-, Fe-, Al- or Cu-based alloy, having a thickness in the range of 10-50 μm that is placed onto substrate (31). A laser beam (36) is positioned and controlled to move over thin foil (33) to melt the foil material only in the desired regions to form a meandering patterned heating track (34). As the foil material (33) only adheres to the ceramic substrate in the laser treated areas, i.e., formed heating track (34), the non-treated areas of the remaining foil material can be removed by, e.g., pressurized air, brushing or lifting the remaining foil off in one piece, depending on the shape of the meander pattern. With this embodiment, a meandering patterned heating track (34) can be produced with narrow gaps, e.g., in the down to 0.5 mm. Moreover, this embodiment is advantageous in that it avoids the risk of blowing conductive material away in direct proximity of the laser spot tracking over conductive foil (33), which may occur when the laser beam heats up a gas around a melt pool formed in powder material. Further, after the patterned heating track (34) formed by the thin foil metal is formed, if a thicker track is desired, another thin foil layer can be applied via SLM or LOM machine processing, i.e., the final track can be formed by a single thin foil or by using an additive process applying plural thin foil layers.

In addition to this higher efficiency on the material consumption, these LALM processes are also far lower in the consumption of electrical energy as compared to thermal spray technology, e.g., lowering the consumption of electricity to 10-20% compared to atmospheric plasma spraying and 50-70% compared to electric arc wire spraying. Also, where applicable, these LALM processes consume more than 90% less technical gases in comparison to atmospheric plasma spray, which is based on, e.g., argon, hydrogen, helium and mixtures thereof as a process gas which is 100% lost during the process. While some of these LALM processes can be performed in an inert gas protective atmosphere, e.g., a protective argon or nitrogen atmosphere, the consumption is lower and/or the inert gas atmosphere can be maintained by a loadlock system.

The structure of an electrically conductive track produced by LALM processes will also be more homogenous compared to thermal spray or ink jet printing, so that the risk of hot spots formed from inconsistent electrical resistivity of the metal layer can be avoided. Further, the specific electrical resistivity of the electrically conductive track applied by LALM processes will be lower compared to thermal spray and ink jet printing due to a lower content of oxides forming in the deposition process and due to a lower porosity. In this manner, the thickness of the electrically conductive track can be reduced as compared to the known art, which leads to lower material requirements to produce the electrically conductive tracks.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

1.-20. (canceled)

21. A process of forming an electric circuit on a substrate, the process comprising:
providing the substrate, the substrate having or including a ceramic surface;
depositing a conductive material on the ceramic surface; and
directing a laser beam onto the conductive material and moving the laser beam relative to the ceramic surface along a predetermined pattern for the electric circuit, thereby melting the conductive material onto the ceramic surface to form a conductive track.

22. The process of claim 21, wherein the process comprises a laser additive layer manufacturing (LALM) process.

23. The process of claim 22, wherein the LALM process is a selective laser melting (SLM) process performed in a protective atmosphere.

24. The process of claim 23, wherein the protective atmosphere is a protective argon atmosphere.

25. The process of claim 21, wherein the conductive material comprises a conductive powder.

26. The process of claim 21, wherein the conductive material comprises a conductive foil.

27. The process of claim 22, wherein the LALM process comprises a laser beam-powder bed fusion (LB-PBF) process.

28. The process of claim 27, wherein the conductive material comprises a conductive powder.

29. The process of claim 22, wherein the LALM process comprises a laminated object manufacturing (LOM) machine.

30. The process of claim 29, wherein the conductive material comprises a conductive foil.

31. The process of claim 21, wherein the predetermined pattern for the electric circuit is a meandering pattern.

32. The process of claim 21, further comprising, prior to depositing the conductive material, at least one of:
pre-patterning the ceramic surface with the laser beam; and
applying a seed layer to which the conductive track is to adhere.

33. The process of claim 21, further comprising adjusting at least one of an intensity of the laser beam, a pulse duration of the laser beam, or a travel speed of a laser spot of the laser beam to generate sufficient adhesion of the conductive track.

34. The process of claim 21, wherein the conductive material comprises at least one of a Ni-based alloy, an Fe-based alloy, an Al-based alloy, or a Cu-based alloy.

35. The process of claim 21, wherein the substrate is selected from the group consisting of a metal substrate and a ceramic substrate.

36. The process of claim 21, wherein the ceramic surface is part of a ceramic layer formed over the substrate.

37. The process of claim 36, wherein the ceramic layer and the conductive track are components of a coating system applied to the substrate.

38. The process of claim 37, further comprising:
applying an insulating layer over the conductive track; and
forming conductive contacts over the insulating layer, wherein the insulating layer and the conductive track are components of the coating system.

39. The process of claim 38, further comprising applying a bond coat on the substrate prior to forming the ceramic layer, and wherein the ceramic layer is formed on the bond coat.
